(19) United States
(12) Patent Application Publication
(10) Pub. No.: US 2025/0321489 A1
(43) Pub. Date: Oct. 16, 2025

(54) METHODS FOR EUV DRY DEVELOPMENT

(71) Applicant: Applied Materials, Inc., Santa Clara, CA (US)

(72) Inventors: Nasrin KAZEM, Santa Clara, CA (US); Bekele WORKU, San Jose, CA (US); Lakmal C. KALUTARAGE, San Jose, CA (US); Madhur SACHAN, Belmont, CA (US); Jayden POTTER, Menlo Park, CA (US); Lauren BAGBY, Palo Alto, CA (US); Muthukumar KALIAPPAN, Santa Clara, CA (US)

(21) Appl. No.: 19/089,694

(22) Filed: Mar. 25, 2025

Related U.S. Application Data
(60) Provisional application No. 63/632,494, filed on Apr. 10, 2024.

(51) Int. Cl. G03F 7/36; G03F 7/004

(52) U.S. Cl. CPC G03F 7/36; G03F 7/0042

(57) ABSTRACT

Embodiments of the present disclosure generally relate to methods for dry developing photoresists, such as metal-oxo photoresists. In one or more embodiments, a method of developing a photoresist is provided and includes exposing a workpiece containing a patterned metal-oxo photoresist disposed on a substrate to a first treatment gas containing a fluorinating agent during a first treatment process and ceasing the exposure of the workpiece of the first treatment gas. The method further includes exposing the workpiece to a second treatment gas containing an organic acid during a second treatment process, the second treatment process contains repeating a treatment cycle one or more times. The treatment cycles includes exposing the workpiece to the second treatment gas, ceasing the exposure of the workpiece of the second treatment gas, exposing the workpiece to a purge gas, and then ceasing the exposure of the workpiece of the purge gas.

### CROSS-REFERENCE TO RELATED APPLICATIONS

This application claims benefit to U.S. Prov. Appl. No. 63/632,494, filed on Apr. 10, 2024, which is herein incorporated by reference in its entirety.

### BACKGROUND

### Field

Embodiments of the present disclosure generally relate to microelectronic fabrication, and more specifically, methods for dry developing photoresists.

### Description of the Related Art

Integrated circuits have evolved into complex devices that can include millions of components (e.g., transistors, capacitors and resistors) on a single chip. Photolithography may be used to form components on the chip. Photolithography has been used in the semiconductor industry for decades for fabricating 2D and 3D patterns in microelectronic devices. In general, the photolithography process involves a wet or dry deposition of a photoresist, irradiation of the photoresist with a selected pattern by an electromagnetic radiation during an exposure process, and then removal of exposed regions (positive tone) or unexposed regions (negative tone) of the photoresist by dissolving in a solvent.

The photoresist should be a radiation sensitive material and upon irradiation a chemical transformation occurs in the exposed part of the film which enables a change in physical properties (e.g., solubility, reactivity) between exposed and unexposed regions. Using this change in physical properties, either exposed or unexposed regions of the photoresist is removed or etched. Thereafter, the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures Higher etch resistant materials also enable thinner films. Thinner films increase the efficiency of the lithographic process.

Therefore, there is a need for improved methods for developing photoresists, especially for dry developing photoresists.

### SUMMARY

Embodiments of the present disclosure generally relate to methods for dry developing photoresists, such as metal-oxo photoresists. Exemplary methods include thermal dry development processes which include exposing the photoresist with two or more treatment gases. The dry development processes provide enhanced development rates, while thoroughly removing the desired portions of the photoresist and byproducts. The dry development processes provide higher resolution of the patterns and lower line-edge roughness (LER) values compared to traditional processes.

In one or more embodiments, a method for developing a photoresist is provided and includes positioning a workpiece in a processing chamber, the workpiece contains a metal-oxo photoresist disposed on a substrate, the metal-oxo photoresist has a radiation formed pattern containing radiation exposed regions and radiation unexposed regions. The method further includes exposing the workpiece to a first treatment gas containing a fluorinating agent during a first treatment process, ceasing the exposure of the workpiece of the first treatment gas, and exposing the workpiece to a second treatment gas may be or include an organic acid during a second treatment process. The second treatment process includes repeating a treatment cycle one or more times. Each of the treatment cycles may include exposing the workpiece to the second treatment gas, ceasing the exposure of the workpiece of the second treatment gas, exposing the workpiece to a purge gas, and then ceasing the exposure of the workpiece of the purge gas.

In some embodiments, a method for developing a photoresist is provided and includes positioning a workpiece in a processing chamber, the workpiece contains a metal-oxo photoresist disposed on a substrate, the metal-oxo photoresist has a radiation formed pattern containing radiation exposed regions and radiation unexposed regions. The method also includes exposing the workpiece to a process cycle to either remove the radiation exposed regions while maintaining the radiation unexposed regions or remove the radiation unexposed regions while maintaining the radiation exposed regions. The process cycle includes exposing the workpiece to a first treatment gas containing a fluorinating agent during a first treatment process. The method further includes ceasing the exposure of the workpiece of the first treatment gas, and exposing the workpiece to a second treatment gas containing an organic acid during a second treatment process, the second treatment process includes repeating a treatment cycle one or more times. Each of the treatment cycles includes exposing the workpiece to the second treatment gas. The method further includes ceasing the exposure of the workpiece of the second treatment gas, exposing the workpiece to a purge gas, and then ceasing the exposure of the workpiece of the purge gas.

In other embodiments, a method of developing a photoresist is provided and includes positioning a workpiece in a processing chamber, wherein the workpiece contains a metal-oxo photoresist disposed on a substrate, and the metal-oxo photoresist contains a radiation formed pattern containing radiation exposed regions and radiation unexposed regions. The method further includes exposing the workpiece to a first treatment gas containing a fluorinating agent during a first treatment process, wherein the fluorinating agent may be or contain hydrogen fluoride, ammonium fluoride, sulfur hexafluoride, nitrogen trifluoride, xenon difluoride, or any combination thereof, and wherein the metal-oxo photoresist contains an organotin-oxo photoresist material or an organoindium-oxo photoresist material in the radiation exposed regions prior to the first treatment process and ceasing the exposure of the workpiece of the first treatment gas. The method also includes exposing the workpiece to a second treatment gas containing an organic acid during a second treatment process, where the second treatment process includes repeating a treatment cycle one or more times. The organic acid may be or contain formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof. Each of the treatment cycles includes exposing the workpiece to the second treatment gas, ceasing the exposure of the workpiece of the second treatment gas, exposing the workpiece to a purge gas, and then ceasing the exposure of the workpiece of the purge gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flow chart of a method for developing a photoresist, as described and discussed in one or more embodiments herein.

FIG. 2 is a flow chart of another method for developing a photoresist, as described and discussed in one or more embodiments herein.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to methods for dry developing photoresists, such as metal-oxo photoresists. Exemplary methods include thermal dry development processes which include exposing the photoresist with two or more treatment gases. The dry development processes provide enhanced development rates, while thoroughly removing the desired portions of the photoresist and byproducts. The dry development processes provide higher resolution of the patterns and lower line-edge roughness (LER) values compared to traditional processes.

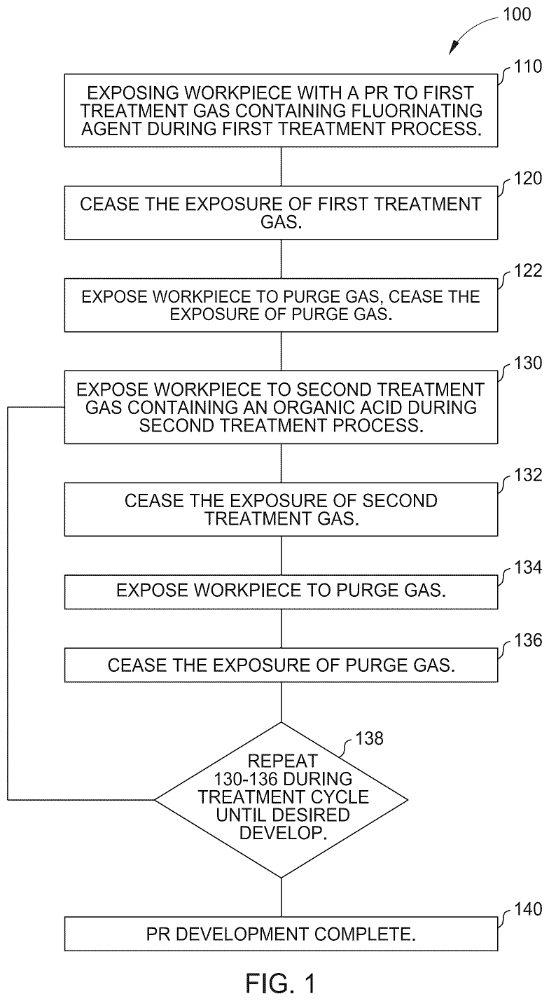

FIG. 1 is a flow chart of a method 100 for developing a photoresist, as described and discussed in one or more embodiments herein. The method 100 includes operations 110-140 as provided in the flow chart. In one or more embodiments, the method includes positioning a workpiece in a processing chamber, such as an etch chamber, a thermal chamber, a vapor deposition chamber (e.g., CVD or ALD chamber), or other types of chambers which are suitable for conducting a dry develop process.

The workpiece contains a metal-oxo photoresist or an organometal-oxo photoresist disposed on a substrate. The metal-oxo photoresist and/or the organometal-oxo photoresist contains a photoresist material which may include one or more metals, such as tin, indium, hafnium, zinc, zirconium, or any combination thereof. In one or more examples, the metal-oxo photoresist contains an organotin-oxo photoresist material. In other examples, the metal-oxo photoresist contains an organoindium-oxo photoresist material. The photoresist material may be deposited by a dry deposition process (e.g., ALD or CVD) or a wet deposition process (e.g., spin-on deposition).

Prior to the start of method 100, the photoresist on the workpiece was exposed to irradiation with a selected pattern by an electromagnetic radiation during an exposure process to produce a radiation formed pattern containing radiation exposed regions and radiation unexposed regions within the photoresist. The radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

In one or more embodiments, the metal-oxo photoresist has a radiation formed pattern containing radiation exposed regions and radiation unexposed regions. In some embodiments of the dry development techniques, the radiation exposed regions are removed and the radiation unexposed regions remain to produce a positive tone resist. In other embodiments of the dry development techniques, the radiation unexposed regions are removed and the radiation exposed regions remain to produce a negative tone resist.

In one or more examples, the metal-oxo photoresist contains an organotin-oxo photoresist material or an organoindium-oxo photoresist material in the radiation exposed regions prior to the first treatment process. The radiation unexposed regions may contain a greater carbon concentration than the radiation exposed regions. In other examples, the metal-oxo photoresist contains an organotin-oxo photoresist material or an organoindium-oxo photoresist material in the radiation unexposed regions prior to the first treatment process. The radiation exposed regions may contain a greater carbon concentration than the radiation unexposed regions.

The method 100 includes exposing the workpiece to a first treatment gas containing one or more fluorinating agents during a first treatment process (operation 110), and ceasing the exposure of the workpiece of the first treatment gas (operation 120). The workpiece is exposed to a purge gas for a predetermined period, then the exposure of the workpiece by the purge gas is ceased or stopped (operation 122). The method 100 further includes exposing the workpiece to a second treatment gas containing at least one or more organic acids during a second treatment process (operations 130-138). The second treatment process includes repeating a treatment cycle one or more times (operations 130-138). Each of the treatment cycles may include exposing the workpiece to the second treatment gas (operation 130), ceasing the exposure of the workpiece of the second treatment gas (operation 132), exposing the workpiece to a purge gas (operation 134), and then ceasing the exposure of the workpiece of the purge gas (operation 136). At operation 138, the treatment cycle of operations 130-136 may be repeated until the desired development of the photoresist is achieved. Thereafter, the development the photoresist is complete at operation 140.

At operation 110 of the method 100, the photoresist on the workpiece is exposed to a first treatment gas containing at least one or more fluorinating agents during a first treatment process. Exemplary fluorinating agents may be or include hydrogen fluoride (HF), ammonium fluoride (NH₄F), sulfur hexafluoride (SF₆), nitrogen trifluoride (NF₃), xenon difluoride (XeF₂), fluorine (F₂), or any combination thereof. In some examples, the first treatment gas may also include one or more diluting gases or carrier gases, such as argon, nitrogen (N₂), neon, helium, or any combination thereof.

In an alternative embodiment, the photoresist on the workpiece is exposed to a first treatment gas containing at least one or more other etchants alone or with any one or more the fluorinating agents at operation 110. Some exemplary etchants may be or include chlorine (Cl₂), bromine (Br₂), iodine (I₂), hydrogen chloride (HCl), hydrogen bromide (HBr), hydrogen iodide (HI), boron trichloride (BCl₃), or any combination thereof. Other exemplary etchants may be one or more halogenating agents, such as thionyl chloride (SOCl₂), methanesulfonyl chloride (CH₃SO₂Cl), trichloromethanesulfonyl chloride (CCl₃SO₂Cl), 4-toluenesulfonyl chloride (tosyl chloride), trimethylsilyl bromide, thionyl bromide (SOBr₂), sulfuryl chloride (SO₂Cl₂), and sulfuryl bromide (SO₂Br₂), oxalyl chloride (ClCOCOCl), tert-butyl hypochlorite ((CH₃)₃COCl), N-chlorophthalimide, 1,3-dichloro-5,5-dimethylhydantoin, trimethylsilyl chloride, HCl, Cl₂, PCl₅, BCl₃, HBr, Br₂, CCl₃Br, CBr₄, 1,2-dibromo-1,1,2,2-tetrachloroethane (Cl₂CBrCBrCl₂), BBr₃, PBr₃, N-bromosuccinimide, N-bromoacetamide, 2-bromo-2-cyano-N,N-dimethylacetamide, 1,3-dibromo-5,5-dimethylhydantoin, 2,4,4,6-tetrabromo-2,5-cyclohexadienone, or any combination thereof.

In one or more examples during the first treatment process, the workpiece and/or the processing region may be heated or maintained at a temperature in a range from about 100° C. to about 300° C., and the processing region may be maintained at a pressure in a range from about 0.1 torr to about 50 torr. In other examples during the first treatment process, the workpiece and/or the processing region may be heated or maintained at a temperature in a range from about 135° C. to about 165° C. and the processing region is maintained at a pressure in a range from about 5 torr to about 25 torr. In some examples during the first treatment process, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr. The flow rate of the first treatment gas may be in a range from about 1 sccm to about 2,000 sccm. In some examples, the workpiece containing the photoresist is exposed to a continuous flow of the first treatment gas during the first treatment process. In other examples, the workpiece containing the photoresist is exposed to discontinuous pulses of the first treatment gas during the first treatment process.

In one or more embodiments, the workpiece containing the photoresist may be exposed to the first treatment gas in a range from about 1 second, about 2 seconds, about 3 seconds, about 5 seconds, about 8 seconds, about 10 seconds, or about 12 seconds to about 15 seconds, about 18 seconds, about 20 seconds, about 25 seconds, about 30 seconds, about 40 seconds, about 45 seconds, about 50 seconds, about 60 seconds, about 75 seconds, or about 90 seconds during the first treatment process. For example, the workpiece containing the photoresist may be exposed to the first treatment gas for about 1 second to about 90 seconds, about 1 second to about 60 seconds, about 1 second to about 50 seconds, about 1 second to about 40 seconds, about 1 second to about 30 seconds, about 1 second to about 20 seconds, about 1 second to about 15 seconds, about 1 second to about 10 seconds, about 1 second to about 8 seconds, about 1 second to about 5 seconds, about 1 second to about 3 seconds, about 2 seconds to about 30 seconds, about 2 seconds to about 20 seconds, about 2 seconds to about 15 seconds, about 2 seconds to about 10 seconds, about 2 seconds to about 8 seconds, about 2 seconds to about 5 seconds, about 2 seconds to about 3 seconds, about 5 seconds to about 30 seconds, about 5 seconds to about 20 seconds, about 5 seconds to about 15 seconds, about 5 seconds to about 10 seconds, about 5 seconds to about 8 seconds, or about 5 seconds to about 7 seconds during the first treatment process.

At operation 120 of the method 100, the first treatment process is ceased or stopped upon obtaining the desired treatment of the photoresist. The exposure of the workpiece and the photoresist by the first treatment gas is ceased or stopped. The metal-oxo photoresist contains an organometal-oxo photoresist material (e.g., organotin-oxo photoresist material or organoindium-oxo photoresist material) in the radiation exposed regions prior to the first treatment process. During the first treatment process (operation 110), the organometal-oxo photoresist material is converted to at least one or more non-volatile or solid materials (e.g., one or more metal-containing photoresist materials). The first treatment process may also produce one or more volatile or gaseous materials from reaction between the organometal-oxo photoresist material and the first treatment gas. In some examples during the first treatment process (operation 110), the organometal-oxo photoresist material is converted to a fluorometal-oxo photoresist material (e.g., fluorotin-oxo photoresist material or fluoroindium-oxo photoresist material).

In one or more embodiments, the metal-oxo photoresist contains an organotin-oxo photoresist material in the radiation exposed regions prior to the first treatment process. The organotin-oxo photoresist material may be converted to one or more fluorotin-oxo photoresist materials (e.g., non-volatile or solid materials) during the first treatment process (operation 110). In other embodiments, the metal-oxo photoresist contains an organoindium-oxo photoresist material in the radiation exposed regions prior to the first treatment process. The organoindium-oxo photoresist material may be converted to one or more fluoroindium-oxo photoresist materials (e.g., non-volatile or solid materials) during the first treatment process (operation 110).

At operation 122 of the method 100, the workpiece containing the photoresist is exposed to a purge gas for a period during a purge process, then the exposure of the workpiece by the purge gas is ceased or stopped. For examples, the method further includes exposing the workpiece to the purge gas after the first treatment process and before the second treatment process at operation 122. The processing environment may be evacuated during the purge process—so to reduce or remove remnants of the first treatment gas, products, byproducts, and/or purge gas. Exemplary purge gas may be or include argon, nitrogen (N₂), hydrogen (H₂), neon, helium, or any combination thereof. The flow rate of the purge gas may be in a range from about 1 sccm to about 2,000 sccm.

In one or more embodiments, the workpiece containing the photoresist may be exposed to the purge gas in a range from about 0.1 seconds, about 0.2 seconds, about 0.3 seconds, about 0.4 seconds, or about 0.5 seconds to about 0.6 seconds, about 0.7 seconds, about 0.8 seconds, about 0.9 seconds, about 1 second to about 1.2 seconds, about 1.5 seconds, about 1.8 seconds, about 2 seconds, about 2.5 seconds, about 3 seconds, about 4 seconds, about 5 seconds, about 6 seconds, about 8 seconds, about 10 seconds, about 12 seconds, about 15 seconds, about 18 seconds, about 20 seconds, about 25 seconds, about 30 seconds, about 40 seconds, about 50 seconds, about 60 seconds, or longer during the purge process at operation 122. For example, the workpiece containing the photoresist may be exposed to the purge gas for about 0.1 seconds to about 60 seconds, about 0.1 seconds to about 40 seconds, about 0.1 seconds to about 30 seconds, about 0.1 seconds to about 25 seconds, about 0.1 seconds to about 20 seconds, about 0.1 seconds to about 15 seconds, about 0.1 seconds to about 12 seconds, about 0.1 seconds to about 10 seconds, about 0.1 seconds to about 8 seconds, about 0.1 seconds to about 5 seconds, about 0.1 seconds to about 4 seconds, about 0.1 seconds to about 3 seconds, about 0.1 seconds to about 2.5 seconds, about 0.1 seconds to about 2 seconds, about 0.1 seconds to about 1.8 seconds, about 0.1 seconds to about 1.5 seconds, about 0.1 seconds to about 1.2 seconds, about 0.1 seconds to about 1 second, about 0.1 seconds to about 0.8 seconds, about 0.1 seconds to about 0.6 seconds, about 0.2 seconds to about 1 second, about 0.3 seconds to about 0.7 seconds, about 0.5 seconds to about 3 seconds, about 0.5 seconds to about 2.5 seconds, about 0.5 seconds to about 2 seconds, about 0.5 seconds to about 1.8 seconds, about 0.5 seconds to about 1.5 seconds, about 0.5 seconds to about 1.2 seconds, about 0.5 seconds to about 1 second, about 0.5 seconds to about 0.8 seconds, about 0.5 seconds to about 0.6 seconds, about 0.8 seconds to about 3 seconds, about 0.8 seconds to about 2.5 seconds, about 0.8 seconds to about 2 seconds, about 0.8 seconds to about 1.8 seconds, about 0.8 seconds to about 1.5 seconds, about 0.8 seconds to about 1.2 seconds, about 0.8 seconds to about 1 second, about 1 second to about 3 seconds, about 1 second to about 2.5 seconds, about 1 second to about 2 seconds, about 1 second to about 1.8 seconds, about 1 second to about 1.5 seconds, or about 1 second to about 1.2 seconds during the purge process at operation 122.

At operation 130 of the method 100, the photoresist on the workpiece is exposed to the second treatment gas containing at least one or more organic acids during the second treatment process (operations 130-138). Exemplary organic acids may be or include formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof. In some examples, the second treatment gas further contains a diluting gas or a carrier gas combined with the organic acid during the second treatment process. Exemplary diluting gases or carrier gases may be or include argon, nitrogen (N₂), hydrogen (H₂), water, neon, helium, or any combination thereof.

In one or more examples during the second treatment process, the workpiece and/or the processing region may be heated or maintained at a temperature in a range from about 100° C. to about 300° C., and the processing region may be maintained at a pressure in a range from about 0.1 torr to about 50 torr (during operations 130-138). In other examples during the second treatment process, the workpiece and/or the processing region may be heated or maintained at a temperature in a range from about 135° C. to about 165° C. and the processing region is maintained at a pressure in a range from about 5 torr to about 25 torr (during operations 130-138). In some examples during the second treatment process, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr (during operations 130-138). The flow rate of the second treatment gas may be in a range from about 1 sccm to about 2,000 sccm. In some examples, the workpiece containing the photoresist is exposed to a continuous flow of the second treatment gas at operation 130 during the second treatment process. In other examples, the workpiece containing the photoresist is exposed to discontinuous pulses of the second treatment gas at operation 130 during the second treatment process.

In one or more embodiments, the workpiece containing the photoresist may be exposed to the second treatment gas in a range from about 0.1 seconds, about 0.2 seconds, about 0.3 seconds, about 0.5 seconds, about 0.6 seconds, about 0.8 seconds, or about 1 second to about 1.2 seconds, about 1.5 seconds, about 1.8 seconds, about 2 seconds, about 2.5 seconds, about 3 seconds, about 3.5 seconds, about 4 seconds, about 4.5 seconds, about 5 seconds, about 6 seconds, about 8 seconds, about 10 seconds, about 12 seconds, about 15 seconds, about 18 seconds, about 20 seconds, about 22 seconds, about 25 seconds, about 28 seconds, about 30 seconds, or longer during each treatment cycle of the second treatment process. For example, the workpiece containing the photoresist may be exposed to the second treatment gas for about 0.5 seconds to about 30 seconds, about 0.5 seconds to about 25 seconds, about 0.5 seconds to about 20 seconds, about 0.5 seconds to about 15 seconds, about 0.5 seconds to about 10 seconds, about 0.5 seconds to about 8 seconds, about 0.5 seconds to about 6 seconds, about 0.5 seconds to about 5 seconds, about 0.5 seconds to about 4 seconds, about 0.5 seconds to about 3 seconds, about 0.5 seconds to about 2 seconds, about 0.5 seconds to about 1.5 seconds, about 0.5 seconds to about 1.2 seconds, about 0.5 seconds to about 1 second, about 0.5 seconds to about 0.8 seconds, about 0.6 seconds to about 5 seconds, about 0.6 seconds to about 4 seconds, about 0.6 seconds to about 3 seconds, about 0.6 seconds to about 2 seconds, about 0.6 seconds to about 1.5 seconds, about 0.6 seconds to about 1.2 seconds, about 0.6 seconds to about 1 second, about 0.6 seconds to about 0.8 seconds, about 0.8 seconds to about 5 seconds, about 0.8 seconds to about 4 seconds, about 0.8 seconds to about 3 seconds, about 0.8 seconds to about 2 seconds, about 0.8 seconds to about 1.5 seconds, about 0.8 seconds to about 1.2 seconds, or about 0.8 seconds to about 1 second during each treatment cycle of the second treatment process.

At operation 132 of the method 100, the exposure of the workpiece and the photoresist by the second treatment gas is ceased or stopped.

At operation 134 of the method 100, the workpiece containing the photoresist is exposed to a purge gas during a purge process, which is occurs in each treatment cycle of the second treatment process. Exemplary purge gas may be or include argon, nitrogen (N₂), hydrogen (H₂), neon, helium, or any combination thereof. The flow rate of the purge gas may be in a range from about 1 sccm to about 2,000 sccm.

In one or more embodiments, the workpiece containing the photoresist may be exposed to the purge gas in a range from about 0.1 seconds, about 0.2 seconds, about 0.3 seconds, about 0.4 seconds, or about 0.5 seconds to about 0.6 seconds, about 0.7 seconds, about 0.8 seconds, about 0.9 seconds, about 1 second to about 1.2 seconds, about 1.5 seconds, about 1.8 seconds, about 2 seconds, about 2.5 seconds, about 3 seconds, about 5 seconds, about 8 seconds, about 10 seconds, about 12 seconds, about 15 seconds, about 18 seconds, about 20 seconds, about 25 seconds, about 30 seconds, about 40 seconds, about 50 seconds, about 60 seconds, or longer during each purge process or each treatment cycle of the second treatment process. For example, the workpiece containing the photoresist may be exposed to the purge gas for about 0.1 seconds to about 60 seconds, about 0.1 seconds to about 40 seconds, about 0.1 seconds to about 30 seconds, about 0.1 seconds to about 25 seconds, about 0.1 seconds to about 20 seconds, about 0.1 seconds to about 15 seconds, about 0.1 seconds to about 12 seconds, about 0.1 seconds to about 10 seconds, about 0.1 seconds to about 8 seconds, about 0.1 seconds to about 5 seconds, about 0.1 seconds to about 4 seconds, about 0.1 seconds to about 3 seconds, about 0.1 seconds to about 2.5 seconds, about 0.1 seconds to about 2 seconds, about 0.1 seconds to about 1.8 seconds, about 0.1 seconds to about 1.5 seconds, about 0.1 seconds to about 1.2 seconds, about 0.1 seconds to about 1 second, about 0.1 seconds to about 0.8 seconds, about 0.1 seconds to about 0.6 seconds, about 0.2 seconds to about 1 second, about 0.3 seconds to about 0.7 seconds, about 0.5 seconds to about 3 seconds, about 0.5 seconds to about 2.5 seconds, about 0.5 seconds to about 2 seconds, about 0.5 seconds to about 1.8 seconds, about 0.5 seconds to about 1.5 seconds, about 0.5 seconds to about 1.2 seconds, about 0.5 seconds to about 1 second, about 0.5 seconds to about 0.8 seconds, about 0.5 seconds to about 0.6 seconds, about 0.8 seconds to about 3 seconds, about 0.8 seconds to about 2.5 seconds, about 0.8 seconds to about 2 seconds, about 0.8 seconds to about 1.8 seconds, about 0.8 seconds to about 1.5 seconds, about 0.8 seconds to about 1.2 seconds, about 0.8 seconds to about 1 second, about 1 second to about 3 seconds, about 1 second to about 2.5 seconds, about 1 second to about 2 seconds, about 1 second to about 1.8 seconds, about 1 second to about 1.5 seconds, or about 1 second to about 1.2 seconds during each purge process or each treatment cycle of the second treatment process.

In one or more examples, the workpiece containing the photoresist may be exposed to the second treatment gas for about 0.5 seconds to about 1.5 seconds and to the purge gas for about 0.25 seconds to about 0.75 seconds during each treatment cycle of the second treatment process. In other examples, the workpiece containing the photoresist may be exposed to the second treatment gas for about 0.8 seconds to about 1.2 seconds and to the purge gas for about 0.3 seconds to about 0.7 seconds during each treatment cycle of the second treatment process. In some examples, the workpiece containing the photoresist may be exposed to the second treatment gas for about 1 second and to the purge gas for about 0.5 seconds during each treatment cycle of the second treatment process.

At operation 136 of the method 100, the exposure of the workpiece and the photoresist by the purge gas is ceased or stopped.

At operation 138 of the method 100, the treatment cycle of operations 130-136 may be repeated until the desired development of the photoresist is achieved. In some embodiments, the treatment cycle of operations 130-136 is conducted a single time. In other embodiments, the treatment cycle of operations 130-136 is conducted multiple times, such as two or more times.

In one or more embodiments, the treatment cycle of operations 130-136 may be conducted or otherwise performed 2 times, 3 times, 4 times, 5 times, about 10 times, about 15 times, about 20 times, about 30 times, about 40 times, about 50 times, about 60 times, about 80 times, about 100 times, about 150 times, or about 180 times to about 200 times, about 220 times, about 250 times, about 280 times, about 300 times, about 320 times, about 350 times, about 380 times, about 400 times, about 450 times, about 500 times, or more times. For example, the treatment cycle of operations 130-136 may be conducted or otherwise performed 2 times to about 400 times, 2 times to about 300 times, 2 times to about 250 times, 2 times to about 220 times, 2 times to about 200 times, 2 times to about 180 times, 2 times to about 150 times, 2 times to about 100 times, 2 times to about 80 times, 2 times to about 50 times, 2 times to about 40 times, 2 times to about 20 times, 2 times to about 10 times, 2 times to about 5 times, about 25 times to about 400 times, about 25 times to about 300 times, about 25 times to about 250 times, about 25 times to about 220 times, about 25 times to about 200 times, about 25 times to about 180 times, about 25 times to about 150 times, about 25 times to about 100 times, about 25 times to about 80 times, about 25 times to about 50 times, about 25 times to about 40 times, about 50 times to about 400 times, about 50 times to about 300 times, about 50 times to about 250 times, about 50 times to about 220 times, about 50 times to about 200 times, about 50 times to about 180 times, about 50 times to about 150 times, about 50 times to about 100 times, about 50 times to about 80 times, about 50 times to about 60 times, about 100 times to about 400 times, about 100 times to about 300 times, about 100 times to about 250 times, about 100 times to about 220 times, about 100 times to about 200 times, about 100 times to about 180 times, about 100 times to about 150 times, about 100 times to about 120 times, about 180 times to about 400 times, about 180 times to about 300 times, about 180 times to about 250 times, about 180 times to about 220 times, or about 180 times to about 200 times.

In other embodiments, the method 100 may include sequentially repeating the first treatment process and the second treatment process one or more times during a process cycle. The process cycle may be repeated in a range from 2 times to about 150 times, about 5 times to about 100 times, about 10 times to about 50 times, or about 15 times to about 25 times. In some examples, for each of the process cycles, the treatment cycle may be repeated in a range from 2 times to about 50 times, about 5 times to about 40 times, about 10 times to about 30 times, or about 15 times to about 25 times.

In one or more embodiments, the workpiece may be contained in a processing region of the processing chamber during the first treatment process, the second treatment process, or both the first treatment process and the second treatment process. In one or more examples, the workpiece and/or the processing region may be heated or maintained at a temperature in a range from about 100° C. to about 300° C. and the processing region may be maintained at a pressure in a range from about 0.1 torr to about 50 torr during the first treatment process, the second treatment process, or both the first treatment process and the second treatment process. In other examples, the workpiece and/or the processing region may be heated or maintained at a temperature in a range from about 135° C. to about 165° C. and the processing region is maintained at a pressure in a range from about 5 torr to about 25 torr during the first treatment process, the second treatment process, or both the first treatment process and the second treatment process. In some examples, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr during the first treatment process, the second treatment process, or both the first treatment process and the second treatment process.

Prior to operation 110, the metal-oxo photoresist contains an organometal-oxo photoresist material in the radiation exposed regions prior to the first treatment process. The organometal-oxo photoresist material may be converted to at least one or more non-volatile or solid materials during the first treatment process (operation 110). Thereafter, the one or more non-volatile or solid materials may converted to one or more volatile or gaseous materials during the second treatment process (operations 130-138). The states of matter of the non-volatile or solid materials and the volatile or gaseous materials are relative to the temperature of the workpiece and/or the processing region during the specified operation.

In one or more examples, the metal-oxo photoresist contains an organometal-oxo photoresist material in the radiation exposed regions prior to the first treatment process. The organometal-oxo photoresist material may be converted to a fluorometal-oxo photoresist material during the first treatment process (operation 110). Thereafter, the fluorometal-oxo photoresist material may converted to metal acetate during the second treatment process (operations 130-138). In other examples, the metal-oxo photoresist contains an organotin-oxo photoresist material in the radiation exposed regions prior to the first treatment process. The organotin-oxo photoresist material may be converted to a fluorotin-oxo photoresist material during the first treatment process (operation 110). Thereafter, the fluorotin-oxo photoresist material may converted to tin acetate during the second treatment process (operations 130-138). In some examples, the metal-oxo photoresist contains an organoindium-oxo photoresist material in the radiation exposed regions prior to the first treatment process. The organoindium-oxo photoresist material may be converted to a fluoroindium-oxo photoresist material during the first treatment process (operation 110). Thereafter, the fluoroindium-oxo photoresist material may converted to indium acetate during the second treatment process (operations 130-138).

At operation 140 of the method 100, the development the photoresist is complete.

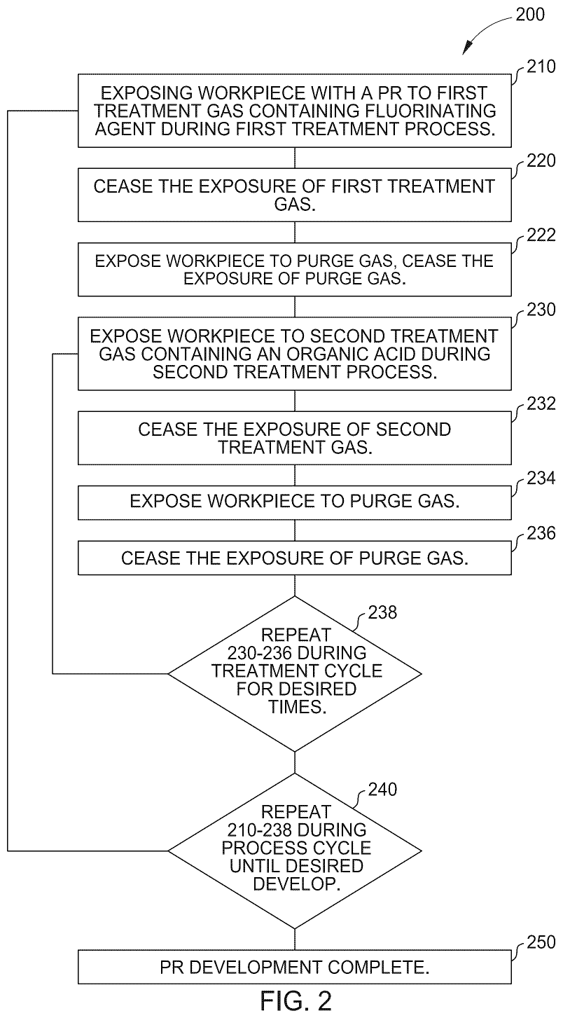

FIG. 2 is a flow chart of a method 200 for developing a photoresist, as described and discussed in one or more embodiments herein. The method 200 includes operations 210-250 as provided in the flow chart. In one or more embodiments, the method includes positioning a workpiece in a processing chamber, such as an etch chamber, a thermal chamber, a vapor deposition chamber (e.g., CVD or ALD chamber), or other types of chambers which are suitable for conducting a dry develop process.

The workpiece contains a metal-oxo photoresist or an organometal-oxo photoresist disposed on a substrate. The metal-oxo photoresist and/or the organometal-oxo photoresist contains a photoresist material which may include one or more metals, such as tin, indium, hafnium, zinc, zirconium, or any combination thereof. In one or more examples, the metal-oxo photoresist contains an organotin-oxo photoresist material. In other examples, the metal-oxo photoresist contains an organoindium-oxo photoresist material. The photoresist material may be deposited by a dry deposition process (e.g., ALD or CVD) or a wet deposition process (e.g., spin-on deposition).

Prior to the start of method 200, the photoresist on the workpiece was exposed to irradiation with a selected pattern by an electromagnetic radiation during an exposure process to produce a radiation formed pattern containing radiation exposed regions and radiation unexposed regions within the photoresist. The radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

In one or more embodiments, the metal-oxo photoresist has a radiation formed pattern containing radiation exposed regions and radiation unexposed regions. In some embodiments of the dry development techniques, the radiation exposed regions are removed and the radiation unexposed regions remain to produce a positive tone resist. In other embodiments of the dry development techniques, the radiation unexposed regions are removed and the radiation exposed regions remain to produce a negative tone resist.

In one or more examples, the metal-oxo photoresist contains an organotin-oxo photoresist material or an organoindium-oxo photoresist material in the radiation exposed regions prior to the first treatment process. The radiation unexposed regions may contain a greater carbon concentration than the radiation exposed regions. In other examples, the metal-oxo photoresist contains an organotin-oxo photoresist material or an organoindium-oxo photoresist material in the radiation unexposed regions prior to the first treatment process. The radiation exposed regions may contain a greater carbon concentration than the radiation unexposed regions.

The method 200 includes exposing the workpiece to a process cycle to either remove the radiation exposed regions of the radiation formed pattern while maintaining the radiation unexposed regions of the radiation formed pattern, or alternatively, remove the radiation unexposed regions of the radiation formed pattern while maintaining the radiation exposed regions of the radiation formed pattern. The process cycle includes sequentially exposing the workpiece and the photoresist to a first treatment process and a second treatment process. For example, the process cycle of the method 200 includes exposing the workpiece to a first treatment gas containing one or more fluorinating agents during the first treatment process (operation 210) and ceasing the exposure of the workpiece of the first treatment gas (operation 220). The workpiece is exposed to a purge gas for a predetermined period, then the exposure of the workpiece by the purge gas is ceased or stopped (operation 222). The process cycle of method 200 further includes exposing the workpiece to a second treatment gas containing one or more organic acids during the second treatment process (operation 230). The second treatment process further includes repeating a treatment cycle one or more times (operation 230-238), such that each of the treatment cycles includes exposing the workpiece to the second treatment gas (operation 230). The process cycle of the method 200 further includes ceasing the exposure of the workpiece of the second treatment gas (operation 232), exposing the workpiece to a purge gas (operation 234), and then ceasing the exposure of the workpiece of the purge gas (operation 236). At operation 238, the treatment cycle of operations 230-236 may be repeated until the desired treatment of the photoresist is achieved. Thereafter, at operation 240, the process cycle of operations 210-238 may be repeated until the desired development of the photoresist is achieved. Thereafter, the development the photoresist is complete at operation 250.

At operation 210 of the method 200, the photoresist on the workpiece is exposed to a first treatment gas containing at least one or more fluorinating agents during a first treatment process. Exemplary fluorinating agents may be or include hydrogen fluoride (HF), ammonium fluoride (NH₄F), sulfur hexafluoride (SF₆), nitrogen trifluoride (NF₃), xenon difluoride (XeF₂), fluorine (F₂), or any combination thereof. In some examples, the first treatment gas may also include one or more diluting gases or carrier gases, such as argon, nitrogen (N₂), neon, helium, or any combination thereof.

In an alternative embodiment, the photoresist on the workpiece is exposed to a first treatment gas containing at least one or more other etchants alone or with any one or more the fluorinating agents at operation 210. Some exemplary etchants may be or include chlorine (Cl₂), bromine (Br₂), iodine (I₂), hydrogen chloride (HCl), hydrogen bromide (HBr), hydrogen iodide (HI), boron trichloride (BCl₃), or any combination thereof. Other exemplary etchants may be one or more halogenating agents, such as thionyl chloride (SOCl₂), methanesulfonyl chloride (CH₃SO₂Cl), trichloromethanesulfonyl chloride (CCl₃SO₂Cl), 4-toluenesulfonyl chloride (tosyl chloride), trimethylsilyl bromide, thionyl bromide (SOBr₂), sulfuryl chloride (SO₂Cl₂), and sulfuryl bromide (SO₂Br₂), oxalyl chloride (ClCOCOCl), tert-butyl hypochlorite ((CH₃)₃COCl), N-chlorophthalimide, 1,3-dichloro-5,5-dimethylhydantoin, trimethylsilyl chloride, HCl, Cl₂, PCl₅, BCl₃, HBr, Br₂, CCl₃Br, CBr₄, 1,2-dibromo-1,1,2,2-tetrachloroethane (Cl₂CBrCBrCl₂), BBr₃, PBr₃, N-bromosuccinimide, N-bromoacetamide, 2-bromo-2-cyano-N,N-dimethylacetamide, 1,3-dibromo-5,5-dimethylhydantoin, 2,4,4,6-tetrabromo-2,5-cyclohexadienone, or any combination thereof.

In one or more examples during the first treatment process, the workpiece and/or the processing region may be heated or maintained at a temperature in a range from about 100° C. to about 300° C., and the processing region may be maintained at a pressure in a range from about 0.1 torr to about 50 torr. In other examples during the first treatment process, the workpiece and/or the processing region may be heated or maintained at a temperature in a range from about 135° C. to about 165° C. and the processing region is maintained at a pressure in a range from about 5 torr to about 25 torr. In some examples during the first treatment process, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr. The flow rate of the first treatment gas may be in a range from about 1 sccm to about 2,000 sccm. In some examples, the workpiece containing the photoresist is exposed to a continuous flow of the first treatment gas during the first treatment process. In other examples, the workpiece containing the photoresist is exposed to discontinuous pulses of the first treatment gas during the first treatment process.

In one or more embodiments, the workpiece containing the photoresist may be exposed to the first treatment gas in a range from about 1 second, about 2 seconds, about 3 seconds, about 5 seconds, about 8 seconds, about 10 seconds, or about 12 seconds to about 15 seconds, about 18 seconds, about 20 seconds, about 25 seconds, about 30 seconds, about 40 seconds, about 45 seconds, about 50 seconds, about 60 seconds, about 75 seconds, or about 90 seconds during the first treatment process. For example, the workpiece containing the photoresist may be exposed to the first treatment gas for about 1 second to about 90 seconds, about 1 second to about 60 seconds, about 1 second to about 50 seconds, about 1 second to about 40 seconds, about 1 second to about 30 seconds, about 1 second to about 20 seconds, about 1 second to about 15 seconds, about 1 second to about 10 seconds, about 1 second to about 8 seconds, about 1 second to about 5 seconds, about 1 second to about 3 seconds, about 2 seconds to about 30 seconds, about 2 seconds to about 20 seconds, about 2 seconds to about 15 seconds, about 2 seconds to about 10 seconds, about 2 seconds to about 8 seconds, about 2 seconds to about 5 seconds, about 2 seconds to about 3 seconds, about 5 seconds to about 30 seconds, about 5 seconds to about 20 seconds, about 5 seconds to about 15 seconds, about 5 seconds to about 10 seconds, about 5 seconds to about 8 seconds, or about 5 seconds to about 7 seconds during the first treatment process.

At operation 220 of the method 200, the first treatment process is ceased or stopped upon obtaining the desired treatment of the photoresist. The exposure of the workpiece and the photoresist by the first treatment gas is ceased or stopped. The metal-oxo photoresist contains an organometal-oxo photoresist material (e.g., organotin-oxo photoresist material or organoindium-oxo photoresist material) in the radiation exposed regions prior to the first treatment process. During the first treatment process (operation 210), the organometal-oxo photoresist material is converted to at least one or more non-volatile or solid materials (e.g., one or more metal-containing photoresist materials). The first treatment process may also produce one or more volatile or gaseous materials from reaction between the organometal-oxo photoresist material and the first treatment gas. In some examples during the first treatment process (operation 210), the organometal-oxo photoresist material is converted to a fluorometal-oxo photoresist material (e.g., fluorotin-oxo photoresist material or fluoroindium-oxo photoresist material).

In one or more embodiments, the metal-oxo photoresist contains an organotin-oxo photoresist material in the radiation exposed regions prior to the first treatment process. The organotin-oxo photoresist material may be converted to one or more fluorotin-oxo photoresist materials (e.g., non-volatile or solid materials) during the first treatment process (operation 210). In other embodiments, the metal-oxo photoresist contains an organoindium-oxo photoresist material in the radiation exposed regions prior to the first treatment process. The organoindium-oxo photoresist material may be converted to one or more fluoroindium-oxo photoresist materials (e.g., non-volatile or solid materials) during the first treatment process (operation 210).

At operation 222 of the method 200, the workpiece containing the photoresist is exposed to a purge gas for a period during a purge process, then the exposure of the workpiece by the purge gas is ceased or stopped. For example, each of the process cycles further includes exposing the workpiece to the purge gas after the first treatment process and before the second treatment process at operation 222. The processing environment may be evacuated during the purge process—so to reduce or remove remnants of the first treatment gas, products, byproducts, and/or purge gas. Exemplary purge gas may be or include argon, nitrogen (N₂), hydrogen (H₂), neon, helium, or any combination thereof. The flow rate of the purge gas may be in a range from about 1 sccm to about 2,000 sccm.

In one or more embodiments, the workpiece containing the photoresist may be exposed to the purge gas in a range from about 0.1 seconds, about 0.2 seconds, about 0.3 seconds, about 0.4 seconds, or about 0.5 seconds to about 0.6 seconds, about 0.7 seconds, about 0.8 seconds, about 0.9 seconds, about 1 second to about 1.2 seconds, about 1.5 seconds, about 1.8 seconds, about 2 seconds, about 2.5 seconds, about 3 seconds, about 4 seconds, about 5 seconds, about 6 seconds, about 8 seconds, about 10 seconds, about 12 seconds, about 15 seconds, about 18 seconds, about 20 seconds, about 25 seconds, about 30 seconds, about 40 seconds, about 50 seconds, about 60 seconds, or longer during the purge process at operation 222. For example, the workpiece containing the photoresist may be exposed to the purge gas for about 0.1 seconds to about 60 seconds, about 0.1 seconds to about 40 seconds, about 0.1 seconds to about 30 seconds, about 0.1 seconds to about 25 seconds, about 0.1 seconds to about 20 seconds, about 0.1 seconds to about 15 seconds, about 0.1 seconds to about 12 seconds, about 0.1 seconds to about 10 seconds, about 0.1 seconds to about 8 seconds, about 0.1 seconds to about 5 seconds, about 0.1 seconds to about 4 seconds, about 0.1 seconds to about 3 seconds, about 0.1 seconds to about 2.5 seconds, about 0.1 seconds to about 2 seconds, about 0.1 seconds to about 1.8 seconds, about 0.1 seconds to about 1.5 seconds, about 0.1 seconds to about 1.2 seconds, about 0.1 seconds to about 1 second, about 0.1 seconds to about 0.8 seconds, about 0.1 seconds to about 0.6 seconds, about 0.2 seconds to about 1 second, about 0.3 seconds to about 0.7 seconds, about 0.5 seconds to about 3 seconds, about 0.5 seconds to about 2.5 seconds, about 0.5 seconds to about 2 seconds, about 0.5 seconds to about 1.8 seconds, about 0.5 seconds to about 1.5 seconds, about 0.5 seconds to about 1.2 seconds, about 0.5 seconds to about 1 second, about 0.5 seconds to about 0.8 seconds, about 0.5 seconds to about 0.6 seconds, about 0.8 seconds to about 3 seconds, about 0.8 seconds to about 2.5 seconds, about 0.8 seconds to about 2 seconds, about 0.8 seconds to about 1.8 seconds, about 0.8 seconds to about 1.5 seconds, about 0.8 seconds to about 1.2 seconds, about 0.8 seconds to about 1 second, about 1 second to about 3 seconds, about 1 second to about 2.5 seconds, about 1 second to about 2 seconds, about 1 second to about 1.8 seconds, about 1 second to about 1.5 seconds, or about 1 second to about 1.2 seconds during the purge process at operation 222.

At operation 230 of the method 200, the photoresist on the workpiece is exposed to the second treatment gas containing at least one or more organic acids during the second treatment process (operations 230-238). Exemplary organic acids may be or include formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof. In some examples, the second treatment gas further contains a diluting gas or a carrier gas combined with the organic acid during the second treatment process. Exemplary diluting gases or carrier gases may be or include argon, nitrogen (N₂), hydrogen (H₂), water, neon, helium, or any combination thereof.

In one or more examples during the second treatment process, the workpiece and/or the processing region may be heated or maintained at a temperature in a range from about 100° C. to about 300° C., and the processing region may be maintained at a pressure in a range from about 0.1 torr to about 50 torr (during operations 230-238). In other examples during the second treatment process, the workpiece and/or the processing region may be heated or maintained at a temperature in a range from about 135° C. to about 165° C. and the processing region is maintained at a pressure in a range from about 5 torr to about 25 torr (during operations 230-238). In some examples during the second treatment process, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr (during operations 230-238). The flow rate of the second treatment gas may be in a range from about 1 sccm to about 2,000 sccm. In some examples, the workpiece containing the photoresist is exposed to a continuous flow of the second treatment gas at operation 230 during the second treatment process. In other examples, the workpiece containing the photoresist is exposed to discontinuous pulses of the second treatment gas at operation 230 during the second treatment process.

In one or more embodiments, the workpiece containing the photoresist may be exposed to the second treatment gas in a range from about 0.1 seconds, about 0.2 seconds, about 0.3 seconds, about 0.5 seconds, about 0.6 seconds, about 0.8 seconds, or about 1 second to about 1.2 seconds, about 1.5 seconds, about 1.8 seconds, about 2 seconds, about 2.5 seconds, about 3 seconds, about 3.5 seconds, about 4 seconds, about 4.5 seconds, about 5 seconds, about 6 seconds, about 8 seconds, about 10 seconds, about 12 seconds, about 15 seconds, about 18 seconds, about 20 seconds, about 22 seconds, about 25 seconds, about 28 seconds, about 30 seconds, or longer during each treatment cycle of the second treatment process. For example, the workpiece containing the photoresist may be exposed to the second treatment gas for about 0.5 seconds to about 30 seconds, about 0.5 seconds to about 25 seconds, about 0.5 seconds to about 20 seconds, about 0.5 seconds to about 15 seconds, about 0.5 seconds to about 10 seconds, about 0.5 seconds to about 8 seconds, about 0.5 seconds to about 6 seconds, about 0.5 seconds to about 5 seconds, about 0.5 seconds to about 4 seconds, about 0.5 seconds to about 3 seconds, about 0.5 seconds to about 2 seconds, about 0.5 seconds to about 1.5 seconds, about 0.5 seconds to about 1.2 seconds, about 0.5 seconds to about 1 second, about 0.5 seconds to about 0.8 seconds, about 0.6 seconds to about 5 seconds, about 0.6 seconds to about 4 seconds, about 0.6 seconds to about 3 seconds, about 0.6 seconds to about 2 seconds, about 0.6 seconds to about 1.5 seconds, about 0.6 seconds to about 1.2 seconds, about 0.6 seconds to about 1 second, about 0.6 seconds to about 0.8 seconds, about 0.8 seconds to about 5 seconds, about 0.8 seconds to about 4 seconds, about 0.8 seconds to about 3 seconds, about 0.8 seconds to about 2 seconds, about 0.8 seconds to about 1.5 seconds, about 0.8 seconds to about 1.2 seconds, or about 0.8 seconds to about 1 second during each treatment cycle of the second treatment process.

At operation 232 of the method 200, the exposure of the workpiece and the photoresist by the second treatment gas is ceased or stopped.

At operation 234 of the method 200, the workpiece containing the photoresist is exposed to a purge gas during a purge process, which is occurs in each treatment cycle of the second treatment process. Exemplary purge gas may be or include argon, nitrogen (N₂), hydrogen (H₂), neon, helium, or any combination thereof. The flow rate of the purge gas may be in a range from about 1 sccm to about 2,000 sccm.

In one or more embodiments, the workpiece containing the photoresist may be exposed to the purge gas in a range from about 0.1 seconds, about 0.2 seconds, about 0.3 seconds, about 0.4 seconds, or about 0.5 seconds to about 0.6 seconds, about 0.7 seconds, about 0.8 seconds, about 0.9 seconds, about 1 second to about 1.2 seconds, about 1.5 seconds, about 1.8 seconds, about 2 seconds, about 2.5 seconds, about 3 seconds, about 5 seconds, about 8 seconds, about 10 seconds, about 12 seconds, about 15 seconds, about 18 seconds, about 20 seconds, about 25 seconds, about 30 seconds, about 40 seconds, about 50 seconds, about 60 seconds, or longer during each purge process or each treatment cycle of the second treatment process. For example, the workpiece containing the photoresist may be exposed to the purge gas for about 0.1 seconds to about 60 seconds, about 0.1 seconds to about 40 seconds, about 0.1 seconds to about 30 seconds, about 0.1 seconds to about 25 seconds, about 0.1 seconds to about 20 seconds, about 0.1 seconds to about 15 seconds, about 0.1 seconds to about 12 seconds, about 0.1 seconds to about 10 seconds, about 0.1 seconds to about 8 seconds, about 0.1 seconds to about 5 seconds, about 0.1 seconds to about 4 seconds, about 0.1 seconds to about 3 seconds, about 0.1 seconds to about 2.5 seconds, about 0.1 seconds to about 2 seconds, about 0.1 seconds to about 1.8 seconds, about 0.1 seconds to about 1.5 seconds, about 0.1 seconds to about 1.2 seconds, about 0.1 seconds to about 1 second, about 0.1 seconds to about 0.8 seconds, about 0.1 seconds to about 0.6 seconds, about 0.2 seconds to about 1 second, about 0.3 seconds to about 0.7 seconds, about 0.5 seconds to about 3 seconds, about 0.5 seconds to about 2.5 seconds, about 0.5 seconds to about 2 seconds, about 0.5 seconds to about 1.8 seconds, about 0.5 seconds to about 1.5 seconds, about 0.5 seconds to about 1.2 seconds, about 0.5 seconds to about 1 second, about 0.5 seconds to about 0.8 seconds, about 0.5 seconds to about 0.6 seconds, about 0.8 seconds to about 3 seconds, about 0.8 seconds to about 2.5 seconds, about 0.8 seconds to about 2 seconds, about 0.8 seconds to about 1.8 seconds, about 0.8 seconds to about 1.5 seconds, about 0.8 seconds to about 1.2 seconds, about 0.8 seconds to about 1 second, about 1 second to about 3 seconds, about 1 second to about 2.5 seconds, about 1 second to about 2 seconds, about 1 second to about 1.8 seconds, about 1 second to about 1.5 seconds, or about 1 second to about 1.2 seconds during each purge process or each treatment cycle of the second treatment process.

In one or more examples, the workpiece containing the photoresist may be exposed to the second treatment gas for about 0.5 seconds to about 1.5 seconds and to the purge gas for about 0.25 seconds to about 0.75 seconds during each treatment cycle of the second treatment process. In other examples, the workpiece containing the photoresist may be exposed to the second treatment gas for about 0.8 seconds to about 1.2 seconds and to the purge gas for about 0.3 seconds to about 0.7 seconds during each treatment cycle of the second treatment process. In some examples, the workpiece containing the photoresist may be exposed to the second treatment gas for about 1 second and to the purge gas for about 0.5 seconds during each treatment cycle of the second treatment process.

At operation 236 of the method 200, the exposure of the workpiece and the photoresist by the purge gas is ceased or stopped.

At operation 238 of the method 200, the treatment cycle of operations 230-236 may be repeated until the desired treatment and/or development of the photoresist is achieved. In some embodiments, the treatment cycle of operations 230-236 is conducted a single time. In other embodiments, the treatment cycle of operations 230-236 is conducted multiple times, such as two or more times.

In one or more embodiments, the treatment cycle of operations 230-236 may be conducted or otherwise performed 2 times, 3 times, 4 times, 5 times, about 10 times, about 15 times, about 20 times, about 30 times, about 40 times, about 50 times, about 60 times, about 80 times, about 100 times, about 150 times, or about 180 times to about 200 times, about 220 times, about 250 times, about 280 times, about 300 times, about 320 times, about 350 times, about 380 times, about 400 times, about 450 times, about 500 times, or more times. For example, the treatment cycle of operations 230-236 may be conducted or otherwise performed 2 times to about 400 times, 2 times to about 300 times, 2 times to about 250 times, 2 times to about 220 times, 2 times to about 200 times, 2 times to about 180 times, 2 times to about 150 times, 2 times to about 100 times, 2 times to about 80 times, 2 times to about 50 times, 2 times to about 40 times, 2 times to about 20 times, 2 times to about 10 times, 2 times to about 5 times, about 25 times to about 400 times, about 25 times to about 300 times, about 25 times to about 250 times, about 25 times to about 220 times, about 25 times to about 200 times, about 25 times to about 180 times, about 25 times to about 150 times, about 25 times to about 100 times, about 25 times to about 80 times, about 25 times to about 50 times, about 25 times to about 40 times, about 50 times to about 400 times, about 50 times to about 300 times, about 50 times to about 250 times, about 50 times to about 220 times, about 50 times to about 200 times, about 50 times to about 180 times, about 50 times to about 150 times, about 50 times to about 100 times, about 50 times to about 80 times, about 50 times to about 60 times, about 100 times to about 400 times, about 100 times to about 300 times, about 100 times to about 250 times, about 100 times to about 220 times, about 100 times to about 200 times, about 100 times to about 180 times, about 100 times to about 150times, about 100 times to about 120 times, about 180 times to about 400 times, about 180 times to about 300 times, about 180 times to about 250 times, about 180 times to about 220 times, or about 180 times to about 200 times.

In one or more embodiments, the workpiece may be contained in a processing region of the processing chamber during the first treatment process, the second treatment process, or both the first treatment process and the second treatment process. In one or more examples, the workpiece and/or the processing region may be heated or maintained at a temperature in a range from about 100° C. to about 300° C. and the processing region may be maintained at a pressure in a range from about 0.1 torr to about 50 torr during the first treatment process, the second treatment process, or both the first treatment process and the second treatment process. In other examples, the workpiece and/or the processing region may be heated or maintained at a temperature in a range from about 135° C. to about 165° C. and the processing region is maintained at a pressure in a range from about 5 torr to about 25 torr during the first treatment process, the second treatment process, or both the first treatment process and the second treatment process. In some examples, the workpiece and/or the processing region may be heated or maintained at a temperature in a range from about 150° C. to about 300° C., such as about 200° C. to about 300° C. or about 250° C. to about 300° C. and the processing region is maintained at a pressure in a range from about 0.1 torr to about 20 torr, such as about 0.5 torr or 1 torr to about 15 torr during the first treatment process, the second treatment process, or both the first treatment process and the second treatment process.

Prior to operation 210, the metal-oxo photoresist contains an organometal-oxo photoresist material in the radiation exposed regions prior to the first treatment process. The organometal-oxo photoresist material may be converted to at least one or more non-volatile or solid materials during the first treatment process (operation 210). Thereafter, the one or more non-volatile or solid materials may converted to one or more volatile or gaseous materials during the second treatment process (operations 230-238). The states of matter of the non-volatile or solid materials and the volatile or gaseous materials are relative to the temperature of the workpiece and/or the processing region during the specified operation.

In one or more examples, the metal-oxo photoresist contains an organometal-oxo photoresist material in the radiation exposed regions prior to the first treatment process. The organometal-oxo photoresist material may be converted to a fluorometal-oxo photoresist material during the first treatment process (operation 210). Thereafter, the fluorometal-oxo photoresist material may converted to metal acetate during the second treatment process (operations 230-238). In other examples, the metal-oxo photoresist contains an organotin-oxo photoresist material in the radiation exposed regions prior to the first treatment process. The organotin-oxo photoresist material may be converted to a fluorotin-oxo photoresist material during the first treatment process (operation 210). Thereafter, the fluorotin-oxo photoresist material may converted to tin acetate during the second treatment process (operations 230-238). In some examples, the metal-oxo photoresist contains an organoindium-oxo photoresist material in the radiation exposed regions prior to the first treatment process. The organoindium-oxo photoresist material may be converted to a fluoroindium-oxo photoresist material during the first treatment process (operation 210). Thereafter, the fluoroindium-oxo photoresist material may converted to indium acetate during the second treatment process (operations 230-238).

At operation 240 of the method 200, the process cycle of operations 210-238 may be repeated until the desired treatment and/or development of the photoresist is achieved. The first treatment process at 210 may be started if the photoresist is not at the desired treatment and/or development level, such as being completely developed.

In one or more embodiments, the process cycle of operations 210-238 may be conducted or otherwise performed 2 times, 3 times, 4 times, 5 times, about 10 times, about 15 times, about 20 times, about 25 times, about 30 times, about 35 times, or about 40 times to about 50 times, about 60 times, about 80 times, about 100 times, about 120 times, about 135 times, about 150 times, about 165 times, about 180 times to about 200 times, about 220 times, about 250 times, about 280 times, about 300 times, or more times. For example, the process cycle of operations 210-238 may be conducted or otherwise performed 2 times to about 300 times, 2 times to about 250 times, 2 times to about 220 times, 2 times to about 200 times, 2 times to about 180 times, 2 times to about 150 times, 2 times to about 100 times, 2 times to about 80 times, 2 times to about 50 times, 2 times to about 40 times, 2 times to about 30 times, 2 times to about 20 times, 2 times to about 10 times, 2 times to about 5 times, about 10 times to about 300 times, about 10 times to about 100 times, about 10 times to about 220 times, about 10 times to about 200 times, about 10 times to about 180 times, about 10 times to about 150 times, about 10 times to about 135 times, about 10 times to about 100 times, about 10 times to about 80 times, about 10 times to about 65 times, about 10 times to about 50 times, about 10 times to about 40 times, about 10 times to about 30 times, about 10 times to about 20 times, about 25 times to about 300 times, about 25 times to about 250 times, about 25 times to about 220 times, about 25 times to about 200 times, about 25 times to about 180 times, about 25 times to about 150 times, about 25 times to about 100 times, about 25 times to about 80 times, about 25 times to about 60 times, about 25 times to about 50 times, or about 25 times to about 35 times.

In one or more examples, the process cycle is repeated in a range from 2 times to about 200 times, and the treatment cycle is repeated in a range from 2 times to about 50 times for each of the process cycles. In other examples, the process cycle is repeated in a range from 2 times to about 50 times, and the treatment cycle is repeated in a range from 2 times to about 400 times for each of the process cycles.

At operation 250 of the method 200, the development the photoresist is complete.

The present disclosure provides, among others, the following embodiments, each of which may be considered as optionally including any alternate embodiments per one or more of the following Clauses 1-62.

Clause 1. A method of developing a photoresist, comprising: positioning a workpiece in a processing chamber, wherein the workpiece comprises a metal-oxo photoresist disposed on a substrate, wherein the metal-oxo photoresist comprises a radiation formed pattern comprising radiation exposed regions and radiation unexposed regions; exposing the workpiece to a first treatment gas comprising a fluorinating agent during a first treatment process; ceasing the exposure of the workpiece of the first treatment gas; and exposing the workpiece to a second treatment gas comprising an organic acid during a second treatment process, wherein the second treatment process comprises repeating a treatment cycle one or more times, and wherein each of the treatment cycles comprises: exposing the workpiece to the second treatment gas; ceasing the exposure of the workpiece of the second treatment gas; exposing the workpiece to a purge gas; and then ceasing the exposure of the workpiece of the purge gas.

Clause 2. The method according to Clause 1, wherein the workpiece is exposed to the first treatment gas for about 1 second to about 60 seconds during the first treatment process.

Clause 3. The method according to Clause 1 or 2, wherein the workpiece is exposed to a continuous flow of the first treatment gas during the first treatment process.

Clause 4. The method according to any one of Clauses 1-3, wherein the workpiece is exposed to discontinuous pulses of the first treatment gas during the first treatment process.

Clause 5. The method according to any one of Clauses 1-4, wherein the workpiece is exposed to the second treatment gas for about 0.5 seconds to about 20 seconds during each treatment cycle of the second treatment process.

Clause 6. The method according to any one of Clauses 1-5, wherein the workpiece is exposed to the purge gas for about 0.1 seconds to about 30 seconds during each treatment cycle of the second treatment process.

Clause 7. The method according to any one of Clauses 1-6, wherein the workpiece is exposed to the second treatment gas for about 0.5 seconds to about 15 seconds and to the purge gas for about 0.5 seconds to about 20 seconds during each treatment cycle of the second treatment process.

Clause 8. The method according to any one of Clauses 1-7, wherein the treatment cycle is repeated in a range from 2 times to about 400 times.

Clause 9. The method according to any one of Clauses 1-8, further comprising sequentially repeating the first treatment process and the second treatment process one or more times during a process cycle.

Clause 10. The method according to any one of Clauses 1-9, wherein the process cycle is repeated in a range from 2 times to about 150 times.

Clause 11. The method according to any one of Clauses 1-10, wherein the treatment cycle is repeated in a range from 2 times to about 50 times for each of the process cycles.

Clause 12. The method according to any one of Clauses 1-11, wherein the fluorinating agent comprises hydrogen fluoride, ammonium fluoride, sulfur hexafluoride, nitrogen trifluoride, xenon difluoride, or any combination thereof.

Clause 13. The method according to any one of Clauses 1-12, wherein the organic acid comprises formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof.

Clause 14. The method according to any one of Clauses 1-13, wherein the workpiece is contained in a processing region of the processing chamber during the first treatment process, the second treatment process, or both the first treatment process and the second treatment process.

Clause 15. The method according to any one of Clauses 1-14, wherein the workpiece and/or the processing region is maintained at a temperature in a range from about 100° C. to about 300° C. during the first treatment process, the second treatment process, or both the first treatment process and the second treatment process.

Clause 16. The method according to any one of Clauses 1-15, wherein the processing region is maintained at a pressure in a range from about 0.1 torr to about 50 torr during the first treatment process, the second treatment process, or both the first treatment process and the second treatment process.

Clause 17. The method according to any one of Clauses 1-16, wherein the workpiece is maintained at a temperature in a range from about 135° C. to about 165° C. and the processing region is maintained at a pressure in a range from about 5 torr to about 25 torr during the first treatment process, the second treatment process, or both the first treatment process and the second treatment process.

Clause 18. The method according to any one of Clauses 1-17, wherein the radiation unexposed regions comprise a greater carbon concentration than the radiation exposed regions.

Clause 19. The method according to any one of Clauses 1-18, wherein the radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

Clause 20. The method according to any one of Clauses 1-19, wherein the metal-oxo photoresist comprises an organometal-oxo photoresist material in the radiation exposed regions prior to the first treatment process.

Clause 21. The method according to any one of Clauses 1-20, wherein the organometal-oxo photoresist material is converted to at least one or more solid materials during the first treatment process.

Clause 22. The method according to any one of Clauses 1-21, wherein the one or more solid materials are converted to one or more gaseous materials during the second treatment process.

Clause 23. The method according to any one of Clauses 1-22, wherein the metal-oxo photoresist comprises an organotin-oxo photoresist material in the radiation exposed regions prior to the first treatment process.

Clause 24. The method according to any one of Clauses 1-23, wherein the organotin-oxo photoresist material is converted to a fluorotin-oxo photoresist material during the first treatment process.

Clause 25. The method according to any one of Clauses 1-24, wherein the fluorotin-oxo photoresist material is converted to tin acetate during the second treatment process.

Clause 26. The method according to any one of Clauses 1-25, wherein the metal-oxo photoresist comprises an organoindium-oxo photoresist material in the radiation exposed regions prior to the first treatment process.

Clause 27. The method according to any one of Clauses 1-26, wherein the organotin-oxo photoresist material is converted to a fluoroindium-oxo photoresist material during the first treatment process.

Clause 28. The method according to any one of Clauses 1-27, wherein the fluoroindium-oxo photoresist material is converted to indium acetate during the second treatment process.

Clause 29. The method according to any one of Clauses 1-28, further comprising exposing the workpiece to the purge gas after the first treatment process and before the second treatment process.

Clause 30. The method according to any one of Clauses 1-29, wherein the purge gas comprises argon, nitrogen (N₂), hydrogen (H₂), neon, helium, or any combination thereof.

Clause 31. The method according to any one of Clauses 1-30, wherein the second treatment gas further comprises a diluting gas or a carrier gas combined with the organic acid during the second treatment process, and wherein the diluting gas or the carrier gas comprises argon, nitrogen (N₂), neon, helium, or any combination thereof.

Clause 32. A method of developing a photoresist, comprising: positioning a workpiece in a processing chamber, wherein the workpiece comprises a metal-oxo photoresist disposed on a substrate, wherein the metal-oxo photoresist comprises a radiation formed pattern comprising radiation exposed regions and radiation unexposed regions; and exposing the workpiece to a process cycle to either remove the radiation exposed regions while maintaining the radiation unexposed regions or remove the radiation unexposed regions while maintaining the radiation exposed regions, wherein the process cycle comprises: exposing the workpiece to a first treatment gas comprising a fluorinating agent during a first treatment process; ceasing the exposure of the workpiece of the first treatment gas; and exposing the workpiece to a second treatment gas comprising an organic acid during a second treatment process, wherein the second treatment process comprises repeating a treatment cycle one or more times, and wherein each of the treatment cycles comprises: exposing the workpiece to the second treatment gas; ceasing the exposure of the workpiece of the second treatment gas; exposing the workpiece to a purge gas; and then ceasing the exposure of the workpiece of the purge gas.

Clause 33. The method according to Clause 32, wherein the process cycle is repeated in a range from 2 times to about 200 times.

Clause 34. The method according to Clause 32 or 33, wherein the treatment cycle is repeated in a range from 2 times to about 50 times for each of the process cycles.

Clause 35. The method according to any one of Clauses 32-34, wherein the process cycle is repeated in a range from 2 times to about 50 times.

Clause 36. The method according to any one of Clauses 32-35, wherein the treatment cycle is repeated in a range from 2 times to about 400 times.

Clause 37. The method according to any one of Clauses 32-36, wherein the workpiece is exposed to the first treatment gas for about 1 second to about 60 seconds during the first treatment process.

Clause 38. The method according to any one of Clauses 32-37, wherein the workpiece is exposed to a continuous flow of the first treatment gas during the first treatment process.

Clause 39. The method according to any one of Clauses 32-38, wherein the workpiece is exposed to discontinuous pulses of the first treatment gas during the first treatment process.

Clause 40. The method according to any one of Clauses 32-39, wherein the workpiece is exposed to the second treatment gas for about 0.5 seconds to about 20 seconds during each treatment cycle of the second treatment process.

Clause 41. The method according to any one of Clauses 32-40, wherein the workpiece is exposed to the purge gas for about 0.1 seconds to about 30 seconds during each treatment cycle of the second treatment process.

Clause 42. The method according to any one of Clauses 32-41, wherein the workpiece is exposed to the second treatment gas for about 0.5 seconds to about 15 seconds and to the purge gas for about 0.5 seconds to about 20 seconds during each treatment cycle of the second treatment process.

Clause 43. The method according to any one of Clauses 32-42, wherein the process cycle further comprises exposing the workpiece to the purge gas after the first treatment process and before the second treatment process.

Clause 44. The method according to any one of Clauses 32-43, wherein the purge gas comprises argon, nitrogen (N₂), hydrogen (H₂), neon, helium, or any combination thereof.

Clause 45. The method according to any one of Clauses 32-44, wherein the fluorinating agent comprises hydrogen fluoride, ammonium fluoride, sulfur hexafluoride, nitrogen trifluoride, xenon difluoride, or any combination thereof.

Clause 46. The method according to any one of Clauses 32-45, wherein the organic acid comprises formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof.

Clause 47. The method according to any one of Clauses 32-46, wherein the workpiece is contained in a processing region of the processing chamber during the first treatment process, the second treatment process, or both the first treatment process and the second treatment process.

Clause 48. The method according to any one of Clauses 32-47, wherein the workpiece and/or the processing region is maintained at a temperature in a range from about 100° C. to about 300° C. during the first treatment process, the second treatment process, or both the first treatment process and the second treatment process.

Clause 49. The method according to any one of Clauses 32-48, wherein the processing region is maintained at a pressure in a range from about 0.1 torr to about 50 torr during the first treatment process, the second treatment process, or both the first treatment process and the second treatment process.

Clause 50. The method according to any one of Clauses 32-49, wherein the workpiece is maintained at a temperature in a range from about 135° C. to about 165° C. and the processing region is maintained at a pressure in a range from about 5 torr to about 25 torr during the first treatment process, the second treatment process, or both the first treatment process and the second treatment process.

Clause 51. The method according to any one of Clauses 32-50, wherein the radiation unexposed regions comprise a greater carbon concentration than the radiation exposed regions.

Clause 52. The method according to any one of Clauses 32-51, wherein the radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

Clause 53. The method according to any one of Clauses 32-52, wherein the metal-oxo photoresist comprises an organometal-oxo photoresist material in the radiation exposed regions prior to the first treatment process.

Clause 54. The method according to any one of Clauses 32-53, wherein the organometal-oxo photoresist material is converted to at least one or more solid materials during the first treatment process.

Clause 55. The method according to any one of Clauses 32-54, wherein the one or more solid materials are converted to one or more gaseous materials during the second treatment process.

Clause 56. The method according to any one of Clauses 32-55, wherein the metal-oxo photoresist comprises an organotin-oxo photoresist material in the radiation exposed regions prior to the first treatment process.

Clause 57. The method according to any one of Clauses 32-56, wherein the organotin-oxo photoresist material is converted to a fluorotin-oxo photoresist material during the first treatment process.

Clause 58. The method according to any one of Clauses 32-57, wherein the fluorotin-oxo photoresist material is converted to tin acetate during the second treatment process.

Clause 59. The method according to any one of Clauses 32-58, wherein the metal-oxo photoresist comprises an organoindium-oxo photoresist material in the radiation exposed regions prior to the first treatment process.

Clause 60. The method according to any one of Clauses 32-59, wherein the organotin-oxo photoresist material is converted to a fluoroindium-oxo photoresist material during the first treatment process.

Clause 61. The method according to any one of Clauses 32-60, wherein the fluoroindium-oxo photoresist material is converted to indium acetate during the second treatment process.

Clause 62. The method according to any one of Clauses 32-61, wherein the second treatment gas further comprises a diluting gas or a carrier gas combined with the organic acid during the second treatment process, and wherein the diluting gas or the carrier gas comprises argon, nitrogen (N₂), neon, helium, or any combination thereof.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of developing a photoresist, comprising:
positioning a workpiece in a processing chamber, wherein the workpiece comprises a metal-oxo photoresist disposed on a substrate, and wherein the metal-oxo photoresist comprises a radiation formed pattern comprising radiation exposed regions and radiation unexposed regions;
exposing the workpiece to a first treatment gas comprising a fluorinating agent during a first treatment process;
ceasing the exposure of the workpiece of the first treatment gas; and
exposing the workpiece to a second treatment gas comprising an organic acid during a second treatment process, wherein the second treatment process comprises repeating a treatment cycle one or more times, and wherein each of the treatment cycles comprises:
exposing the workpiece to the second treatment gas;
ceasing the exposure of the workpiece of the second treatment gas;
exposing the workpiece to a purge gas; and then
ceasing the exposure of the workpiece of the purge gas.

2. The method of claim 1, wherein the workpiece is exposed to:
the first treatment gas for about 1 second to about 60 seconds during the first treatment process;
the second treatment gas for about 0.5 seconds to about 20 seconds during each treatment cycle of the second treatment process; and
the purge gas for about 0.1 seconds to about 30 seconds during each treatment cycle of the second treatment process.

3. The method of claim 1, wherein the treatment cycle is repeated in a range from 2 times to about 400 times.

4. The method of claim 1, further comprising sequentially repeating the first treatment process and the second treatment process one or more times during a process cycle, wherein the process cycle is repeated in a range from 2 times to about 150 times.

5. The method of claim 1, wherein the fluorinating agent comprises hydrogen fluoride, ammonium fluoride, sulfur hexafluoride, nitrogen trifluoride, xenon difluoride, or any combination thereof, and wherein the organic acid comprises formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof.

6. The method of claim 1, wherein the workpiece is contained in a processing region of the processing chamber during the first treatment process, the second treatment process, or both the first treatment process and the second treatment process, and wherein the workpiece is maintained at a temperature in a range from about 135° C. to about 165° C. and the processing region is maintained at a pressure in a range from about 5 torr to about 25 torr during the first treatment process, the second treatment process, or both the first treatment process and the second treatment process.

7. The method of claim 1, wherein the radiation unexposed regions comprise a greater carbon concentration than the radiation exposed regions, and wherein the radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

8. The method of claim 1, wherein the metal-oxo photoresist comprises an organometal-oxo photoresist material in the radiation exposed regions prior to the first treatment process, wherein the organometal-oxo photoresist material is converted to at least one or more solid materials during the first treatment process, and wherein the one or more solid materials are converted to one or more gaseous materials during the second treatment process.

9. The method of claim 1, wherein the metal-oxo photoresist comprises an organotin-oxo photoresist material in the radiation exposed regions prior to the first treatment process, wherein the organotin-oxo photoresist material is converted to a fluorotin-oxo photoresist material during the first treatment process, and wherein the fluorotin-oxo photoresist material is converted to tin acetate during the second treatment process.

10. The method of claim 1, wherein the metal-oxo photoresist comprises an organoindium-oxo photoresist material in the radiation exposed regions prior to the first treatment process, wherein the organotin-oxo photoresist material is converted to a fluoroindium-oxo photoresist material during the first treatment process, and wherein the fluoroindium-oxo photoresist material is converted to indium acetate during the second treatment process.

11. A method of developing a photoresist, comprising:
positioning a workpiece in a processing chamber, wherein the workpiece comprises a metal-oxo photoresist disposed on a substrate, and wherein the metal-oxo photoresist comprises a radiation formed pattern comprising radiation exposed regions and radiation unexposed regions; and
exposing the workpiece to a process cycle to either remove the radiation exposed regions while maintaining the radiation unexposed regions or remove the radiation unexposed regions while maintaining the radiation exposed regions, wherein the process cycle comprises:
exposing the workpiece to a first treatment gas comprising a fluorinating agent during a first treatment process;
ceasing the exposure of the workpiece of the first treatment gas; and
exposing the workpiece to a second treatment gas comprising an organic acid during a second treatment process, wherein the second treatment process comprises repeating a treatment cycle one or more times, and wherein each of the treatment cycles comprises:
exposing the workpiece to the second treatment gas;
ceasing the exposure of the workpiece of the second treatment gas;
exposing the workpiece to a purge gas; and then
ceasing the exposure of the workpiece of the purge gas.

12. The method of claim 11, wherein the treatment cycle is repeated in a range from 2 times to about 50 times for each of the process cycles, and wherein the process cycle is repeated in a range from 2 times to about 50 times.

13. The method of claim 11, wherein the workpiece is exposed to the second treatment gas for about 0.5 seconds to about 15 seconds and to the purge gas for about 0.5 seconds to about 20 seconds during each treatment cycle of the second treatment process.

14. The method of claim 11, wherein the fluorinating agent comprises hydrogen fluoride, ammonium fluoride, sulfur hexafluoride, nitrogen trifluoride, xenon difluoride, or any combination thereof, and wherein the organic acid comprises formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof.

15. The method of claim 11, wherein the workpiece is contained in a processing region of the processing chamber during the first treatment process, the second treatment process, or both the first treatment process and the second treatment process, and wherein the workpiece is maintained at a temperature in a range from about 135° C. to about 165° C. and the processing region is maintained at a pressure in a range from about 5 torr to about 25 torr during the first treatment process, the second treatment process, or both the first treatment process and the second treatment process.

16. The method of claim 11, wherein the radiation unexposed regions comprise a greater carbon concentration than the radiation exposed regions, and wherein the radiation exposed regions of the radiation formed pattern were exposed to one or more types of electromagnetic radiation selected from ultraviolet (UV), extreme ultraviolet (EUV), deep ultraviolet (DUV), electron beam (EB), or any combination thereof.

17. The method of claim 11, wherein the metal-oxo photoresist comprises an organotin-oxo photoresist material in the radiation exposed regions prior to the first treatment process, wherein the organotin-oxo photoresist material is converted to a fluorotin-oxo photoresist material during the first treatment process, and wherein the fluorotin-oxo photoresist material is converted to tin acetate during the second treatment process.

18. The method of claim 11, wherein the metal-oxo photoresist comprises an organoindium-oxo photoresist material in the radiation exposed regions prior to the first treatment process, wherein the organotin-oxo photoresist material is converted to a fluoroindium-oxo photoresist material during the first treatment process, and wherein the fluoroindium-oxo photoresist material is converted to indium acetate during the second treatment process.

19. A method of developing a photoresist, comprising:
positioning a workpiece in a processing chamber, wherein the workpiece comprises a metal-oxo photoresist disposed on a substrate, and wherein the metal-oxo photoresist comprises a radiation formed pattern comprising radiation exposed regions and radiation unexposed regions;
exposing the workpiece to a first treatment gas comprising a fluorinating agent during a first treatment process, wherein the fluorinating agent comprises hydrogen fluoride, ammonium fluoride, sulfur hexafluoride, nitrogen trifluoride, xenon difluoride, or any combination thereof, and wherein the metal-oxo photoresist comprises an organotin-oxo photoresist material or an organoindium-oxo photoresist material in the radiation exposed regions prior to the first treatment process;
ceasing the exposure of the workpiece of the first treatment gas; and
exposing the workpiece to a second treatment gas comprising an organic acid during a second treatment process, wherein the second treatment process comprises repeating a treatment cycle one or more times, wherein the organic acid comprises formic acid, acetic acid, propanoic acid, lactic acid, oxalic acid, trifluoroacetic acid, difluoroacetic acid, monofluoroacetic acid, trichloroacetic acid, tribromoacetic acid, triiodoacetic acid, isomers thereof, or any combination thereof, and wherein each of the treatment cycles comprises:
exposing the workpiece to the second treatment gas;
ceasing the exposure of the workpiece of the second treatment gas;
exposing the workpiece to a purge gas; and then
ceasing the exposure of the workpiece of the purge gas.

20. The method of claim 19, wherein:
the organotin-oxo photoresist material is converted to a fluorotin-oxo photoresist material during the first treatment process, and the fluorotin-oxo photoresist material is converted to tin acetate during the second treatment process; or
the organotin-oxo photoresist material is converted to a fluoroindium-oxo photoresist material during the first treatment process, and the fluoroindium-oxo photoresist material is converted to indium acetate during the second treatment process.
